(19) United States
(12) Patent Application Publication
(10) Pub. No.: US 2026/0214999 A1
(43) Pub. Date: Jul. 23, 2026

(54) BI-DIRECTIONAL SEMICONDUCTOR-CONTROLLED RECTIFIER WITH DIRECT BACKSIDE CONTACTS

(71) Applicant: INTERNATIONAL BUSINESS MACHINES CORPORATION, ARMONK, NY (US)

(72) Inventors: Robert Gauthier, Williston, VT (US); Anindya Nath, Watervliet, NY (US); Masoud Zabihi, Schenectady, NY (US); Anthony I-Chih Chou, Guilderland, NY (US)

(21) Appl. No.: 19/034,503

(22) Filed: Jan. 22, 2025

(51) Int. Cl. H10D 89/60; H10D 64/01; H10D 84/01; H10D 84/40

(52) U.S. Cl. CPC H10D 89/713; H10D 64/01; H10D 84/0109; H10D 84/40

(57) ABSTRACT

A semiconductor device includes a first well region, a second well region and a third well region adjacent to each other, the second well region is located between the first well region and the third well region, a first frontside doped region and a second frontside doped region over the first well region, a first frontside contact and a second frontside contact over the first frontside doped region and the second frontside doped region, respectively, a first backside doped region on a lower portion of the first well region on a backside of the semiconductor device, and a second backside doped region and a third backside doped region on a lower portion of the third well region on the backside of the semiconductor device, respectively.

### BACKGROUND

### Technical Field

The present disclosure generally relates to semiconductors, and more particularly, to bi-directional semiconductor-controlled rectifier with direct backside contacts structure, and methods of creation thereof.

### Description of Related Art

The continuous miniaturization of transistors and their increasing density on chips epitomize the semiconductor industry’s innovation, largely adhering to Moore’s Law. This trend has led to transistors shrinking to nanometer scales, allowing millions and even billions to fit on a single chip, significantly enhancing computational power and energy efficiency. The evolution towards system-on-chip architectures integrates various functionalities, including processing and sensing, on one chip.

### SUMMARY

According to an embodiment, a semiconductor device includes a first well region, a second well region and a third well region adjacent to each other, the second well region is located between the first well region and the third well region, a first frontside doped region and a second frontside doped region over the first well region, a first frontside contact and a second frontside contact over the first frontside doped region and the second frontside doped region, respectively, a first backside doped region on a lower portion of the first well region on a backside of the semiconductor device, and a second backside doped region and a third backside doped region on a lower portion of the third well region on the backside of the semiconductor device, respectively.

In one embodiment, the semiconductor device includes a first backside contact and a second backside contact below the first backside doped region and the third backside doped region, respectively, and shallow trench isolation (STI) between the second well region and a frontside of the semiconductor device.

In one embodiment, the semiconductor device includes a backside interconnect below the semiconductor device, a first backside metal contact and a second backside metal contact connecting the second backside contact and the third backside contact to the backside interconnect, respectively, and a spacer over sidewalls of the first backside metal contact and the second backside metal contact.

In one embodiment, the semiconductor device is a vertical bi-directional semiconductor-controlled rectifier (SCR), and an anode and a corresponding n+ diffusion in the same p-well are wired to a back end of line (BEOL) on the frontside of the semiconductor device.

In one embodiment, a cathode junction and a corresponding p-well contact are formed on the backside of the semiconductor device.

In one embodiment, the second backside doped region is an N-type doped region, and the third backside doped region is a P-type doped region.

In one embodiment, the second backside doped region and the third doped region are at least partially intruding into the third well region.

In one embodiment, the semiconductor device is vertically isolated by a low-k interlayer dielectric and horizontally by floating N-wells.

In one embodiment, the semiconductor device is a bi-directional semiconductor-controlled rectifier.

According to an embodiment, a method for fabrication of a semiconductor device includes forming a first well region, a second well region and a third well region adjacent to each other, the second well region is located between the first well region and the third well region, forming a first frontside doped region and a second frontside doped region over the first well region, forming a first frontside contact and a second frontside contact over the first frontside doped region and the second frontside doped region, respectively, forming a first backside doped region on a lower portion of the first well region on a backside of the semiconductor device, and forming a second backside doped region and a third backside doped region on a lower portion of the third well region on the backside of the semiconductor device, respectively.

In one embodiment, the method includes forming a first backside contact and a second backside contact below the first backside doped region and the third backside doped region, respectively, and forming shallow trench isolation (STI) between the second well region and a frontside of the semiconductor device.

In one embodiment, the method includes forming a backside interconnect below the semiconductor device, forming a first backside metal contact and a second backside metal contact connecting the second backside contact and the third backside contact to the backside interconnect, respectively and forming a spacer over sidewalls of the first backside metal contact and the second backside metal contact.

In one embodiment, the method includes electrically connecting an anode and a corresponding diffusion in the same p-well to a back end of line (BEOL) on the frontside of the semiconductor device, and the semiconductor device is a vertical bi-directional semiconductor-controlled rectifier (SCR).

In one embodiment, the method includes forming a cathode junction and a corresponding p-well contact on the backside of the semiconductor device.

In one embodiment, the method includes doping the second backside doped region with an N-type dopant, and doping the third backside doped region with a P-type dopant.

In one embodiment, the method includes at least partially intruding the second backside doped region and the third doped region into the third well region.

In one embodiment, the method includes vertically isolating the semiconductor device by a low-k interlayer dielectric; and horizontally isolating the semiconductor device by floating N-wells.

In one embodiment, the semiconductor device is a bi-directional semiconductor-controlled rectifier.

According to an embodiment, a semiconductor device includes a vertical bi-directional semiconductor-controlled rectifier (SCR), and an anode and a corresponding n+ diffusion in the same p-well are wired to a back end of line (BEOL) on the frontside of the semiconductor device, and a cathode junction and a corresponding p-well contact are formed on a backside of the semiconductor device.

In one embodiment, the semiconductor device includes a first well region, a second well region and a third well region adjacent to each other, the second well region is located between the first well region and the third well region. The anode includes a first frontside doped region and a second frontside doped region over the first well region, and a first frontside contact and a second frontside contact over the first frontside doped region and the second frontside doped region, respectively. The cathode includes a first backside doped region and a second backside doped region on a lower portion of the third well region on the backside of the semiconductor device, respectively and a first backside contact and a second backside contact below the first backside doped region and the second backside doped region, respectively.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates a conventional low triggered bi-directional semiconductor-controlled rectifier.

FIGS. 2A-2B illustrate a semiconductor device, in accordance with some embodiments.

FIGS. 3A-3F illustrate acts in preparing frontside of the semiconductor device, in accordance with some embodiments.

FIG. 4 illustrates a semiconductor device after the front end of line processes, in accordance with some embodiments.

FIG. 5 illustrates a semiconductor device after the middle of line and back end of line processes, in accordance with some embodiments.

FIG. 6 illustrates a semiconductor device after wafer flip and substrate removal, in accordance with some embodiments.

FIG. 7 illustrates a semiconductor device after the removal of the etch stop layer, in accordance with some embodiments.

FIG. 8 illustrates a semiconductor device after the formation of backside interlayer dielectric, in accordance with some embodiments.

FIG. 9 illustrates a semiconductor device after the patterning of the backside doped regions, in accordance with some embodiments.

FIG. 10 illustrates a semiconductor device after the contact metallization, in accordance with some embodiments.

FIG. 11 illustrates a semiconductor device after the patterning of the backside doped regions, in accordance with some embodiments.

FIG. 12 illustrates a semiconductor device after the contact metallization and N-type doped region formation, in accordance with some embodiments.

FIG. 13 illustrates a semiconductor device after the backside contact patterning, in accordance with some embodiments.

FIG. 14 illustrates a semiconductor device after the formation of the spacer, in accordance with some embodiments.

FIG. 15 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

According to an embodiment, a semiconductor device includes a first well region, a second well region and a third well region adjacent to each other, the second well region is located between the first well region and the third well region, a first frontside doped region and a second frontside doped region over the first well region, a first frontside contact and a second frontside contact over the first frontside doped region and the second frontside doped region, respectively, a first backside doped region on a lower portion of the first well region on a backside of the semiconductor device, and a second backside doped region and a third backside doped region on a lower portion of the third well region on the backside of the semiconductor device, respectively. As such, the semiconductor device offers higher area efficiency compared to conventional devices.

In one embodiment, the semiconductor device includes a first backside contact and a second backside contact below the first backside doped region and the third backside doped region, respectively, and shallow trench isolation (STI) between the second well region and a frontside of the semiconductor device. The backside contacts connect the semiconductor device via the backside.

In one embodiment, the semiconductor device includes a backside interconnect below the semiconductor device, a first backside metal contact and a second backside metal contact connecting the second backside contact and the third backside contact to the backside interconnect, respectively, and a spacer over sidewalls of the first backside metal contact and the second backside metal contact. The backside interconnect facilitates connection via the backside of the semiconductor device.

In one embodiment, the semiconductor device is a vertical bi-directional semiconductor-controlled rectifier (SCR), and wherein an anode and a corresponding n+ diffusion in the same p-well are wired to a back end of line (BEOL) on the frontside of the semiconductor device. The semiconductor device can serve as a reduced-area BiSCR.

In one embodiment, a cathode junction and a corresponding p-well contact are formed on the backside of the semiconductor device. Formation of the cathode at the backside and the anode on the frontside can reduce total SCR device area by as much as 50%.

In one embodiment, the second backside doped region is an N-type doped region, and the third backside doped region is a P-type doped region. Various dopants can be used for doping.

In one embodiment, the second backside doped region and the third doped region are at least partially intruding into the third well region. The partial intrusion further reduces the necessary area for the SCR device.

In one embodiment, the semiconductor device is vertically isolated by a low-k interlayer dielectric and horizontally by floating N-wells. ILD can isolate various components from crosstalk.

In one embodiment, the semiconductor device is a bi-directional semiconductor-controlled rectifier. The BiSCR is a smaller in size compared to conventional devices.

According to an embodiment, a method for fabrication of a semiconductor device includes forming a first well region, a second well region and a third well region adjacent to each other, the second well region is located between the first well region and the third well region, forming a first frontside doped region and a second frontside doped region over the first well region, forming a first frontside contact and a second frontside contact over the first frontside doped region and the second frontside doped region, respectively, forming a first backside doped region on a lower portion of the first well region on a backside of the semiconductor device, and forming a second backside doped region and a third backside doped region on a lower portion of the third well region on the backside of the semiconductor device, respectively. As such, the semiconductor device offers higher area efficiency compared to conventional devices.

In one embodiment, the method includes forming a first backside contact and a second backside contact below the first backside doped region and the third backside doped region, respectively, and forming shallow trench isolation (STI) between the second well region and a frontside of the semiconductor device. The backside contacts connect the semiconductor device via the backside.

In one embodiment, the method includes forming a backside interconnect below the semiconductor device, forming a first backside metal contact and a second backside metal contact connecting the second backside contact and the third backside contact to the backside interconnect, respectively and forming a spacer over sidewalls of the first backside metal contact and the second backside metal contact. The backside interconnect facilitates connection via the backside of the semiconductor device.

In one embodiment, the method includes electrically connecting an anode and a corresponding n+ diffusion in the same p-well to a back end of line (BEOL) on the frontside of the semiconductor device, and the semiconductor device is a vertical bi-directional semiconductor-controlled rectifier (SCR). The semiconductor device can serve as a reduced-area BiSCR.

In one embodiment, the method includes forming a cathode junction and a corresponding p-well contact on the backside of the semiconductor device. Formation of the cathode at the backside and the anode on the frontside can reduce total SCR device area by as much as 50%.

In one embodiment, the method includes doping the second backside doped region with an N-type dopant, and doping the third backside doped region with a P-type dopant. Various dopant can be used for doping the semiconductor device.

In one embodiment, the method includes at least partially intruding the second backside doped region and the third doped region into the third well region. The partial intrusion further reduces the necessary area for the SCR device.

In one embodiment, the method includes vertically isolating the semiconductor device by a low-k interlayer dielectric; and horizontally isolating the semiconductor device by floating N-wells. ILD can isolate various components from crosstalk.

In one embodiment, the semiconductor device is a bi-directional semiconductor-controlled rectifier. The BiSCR is a smaller in size compared to conventional devices.

According to an embodiment, a semiconductor device includes a vertical bi-directional semiconductor-controlled rectifier (SCR), and an anode and a corresponding n+ diffusion in the same p-well contact are wired to a back end of line (BEOL) on the frontside of the semiconductor device, and a cathode junction and a corresponding p-well contact are formed on a backside of the semiconductor device.

In one embodiment, the semiconductor device includes a first well region, a second well region and a third well region adjacent to each other, the second well region is located between the first well region and the third well region. The anode includes a first frontside doped region and a second frontside doped region over the first well region, and a first frontside contact and a second frontside contact over the first frontside doped region and the second frontside doped region, respectively. The cathode includes a first backside doped region and a second backside doped region on a lower portion of the third well region on the backside of the semiconductor device, respectively and a first backside contact and a second backside contact below the first backside doped region and the second backside doped region, respectively. As such, the semiconductor device offers higher area efficiency compared to conventional devices.

The semiconductor industry continually seeks methods to improve device performance, reduce footprint, and enhance power distribution in advanced integrated circuits. One increasingly popular approach is the use of backside interconnect, where metal wiring and connections are placed on the wafer’s underside rather than solely on the frontside. Traditionally, all interconnect layers and metal routing have been located above the active devices on the front surface of the silicon wafer, contributing to routing congestion, parasitic resistances, and unwanted signal delays. By implementing interconnects at the backside, engineers can relieve frontside crowding, achieve shorter conduction paths for power and ground distributions, and improve thermal management. This backside approach can also free up valuable frontside real estate for more complex or numerous active devices, leading to higher integration density and better overall chip performance.

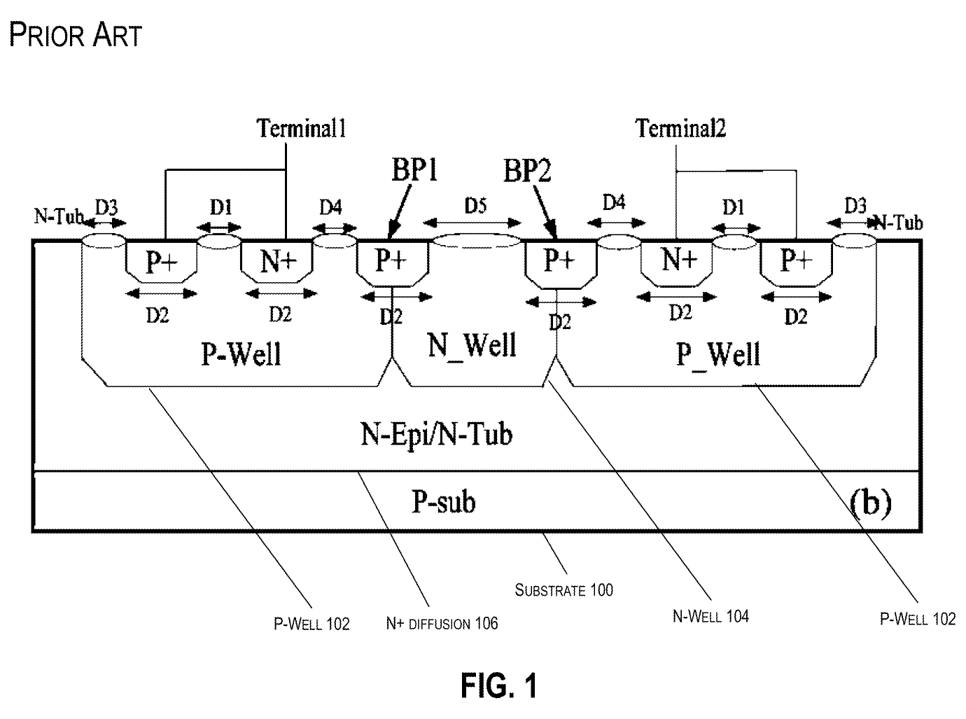

FIG. 1 illustrates a conventional low trigger bi-directional SCR, which is constructed using regions of N-type and P-type doping integrated into a substrate 100. A P-well 102 and an N-well 104 are formed within the substrate 100. A P-well 102, enriched with acceptor dopants such as boron, increases the hole concentration, while an N-well 104, introduced with donor dopants such as phosphorus or arsenic, increases the electron concentration. Heavily doped diffusion regions are introduced into the wells. An N+ diffusion region 106 is created by implanting a high concentration of donor impurities into selected areas, typically within or near the P-well 102. Likewise, a P+ diffusion region is formed by implanting a high concentration of acceptor impurities, often within or near the N-well 104. A conventional SCR typically consists of a four-layer stack: P-N-P-N. In the bi-directional configuration, the SCR is essentially symmetrical, allowing current flow in either direction once triggered. Thus, a low trigger bi-directional SCR is composed of two opposite-facing PNPN structures sharing common regions. When forward biased in one direction, one half of the structure can trigger into conduction; when the polarity is reversed, the other half triggers. This symmetry ensures the SCR can clamp voltage spikes from both polarities.

The low trigger characteristic is achieved by doping concentrations and junction depths of the N+ diffusion region 106 and P+ diffusion region, as well as the doping profiles in the P-well 102 and N-well 104. By carefully selecting these parameters, the voltage at which the SCR transitions from a non-conductive state to a conductive one—known as the trigger voltage—is reduced (e.g., minimized). The trigger event typically involves a small initial current injection or a localized avalanche breakdown that initiates regenerative transistor action inside the PNPN structure. This action rapidly switches the SCR into a low-resistance, high-current conduction mode.

Disclosed is a bi-directional SCR device integrated with direct backside contacts to enhance current conduction, improve device density, and facilitate efficient heat dissipation. The bi-directional SCR conducts current in both forward and reverse directions once triggered, making it suitable for handling transient events that may occur from either polarity. The disclosed semiconductor device is formed on a semiconductor substrate, typically silicon, into which wells of opposite doping types are introduced. Heavily doped regions of N-type and P-type material are then created within these wells. Arranged in a symmetrical manner, these doped regions form the PNPN structure characteristic of an SCR. When the applied voltage in either direction exceeds a certain threshold, internal transistor action causes the SCR to switch from a high-resistance state to a low-resistance state, allowing large currents to flow.

Direct backside contacts are conductive connections formed at the rear surface of the wafer. By tapping into the device from the backside, the contacts reduce frontside routing complexity and electrical resistance, improving the SCR’s overall efficiency. Additionally, ballasting resistance—integrated into certain doped areas—helps ensure that current is evenly distributed, preventing localized failures and enhancing the device’s robustness. The design considerations, including the symmetrical doping profiles, direct backside contacts, and ballasting resistance, combine to produce a bi-directional SCR capable of reliably clamping voltage transients. Such a semiconductor device can be valuable for electrostatic discharge (ESD) protection in advanced integrated circuits, where miniaturization and high performance are critical.

Within this evolving landscape of backside interconnect and advanced device architectures, the bi-directional silicon-controlled rectifier, also known as bi-directional silicon-controlled rectifier (BiSCR), emerges as a compelling solution for high-current and high-voltage switching applications. A BiSCR is a type of thyristor device that can conduct current in both directions once triggered, functioning similarly to a switch that can be turned on by applying a trigger current at its gate. Once activated, it provides a robust, low-resistance conduction path until the current drops below a certain threshold, at which point it stops conducting. This inherently stable and high-current-capable behavior makes the BiSCR ideal for various power electronics, automotive systems, and industrial control circuits.

One particularly important application for the BiSCR lies in radio frequency (RF) electrostatic discharge (ESD) protection. High-frequency RF circuits, such as those found in wireless communication devices or high-speed data links, demand ESD protection solutions that not only handle large ESD stress currents but also introduce very low (e.g., minimal) additional load or parasitic effects to the sensitive RF front end. The BiSCR excels here because it can clamp large ESD-induced surges, safely shunting them away from vulnerable circuitry, while maintaining a relatively low capacitance. Low capacitance is important in RF environments, as even small parasitic capacitances can degrade signal integrity, reduce bandwidth, and impair overall system performance.

In addition, the growing trend toward backside interconnect can further complement the use of BiSCR devices. By routing critical power and ground lines through the backside of the wafer, robust ESD current paths can be obtained. This synergy between backside interconnect technology and BiSCR-based ESD clamps can help realize more compact, reliable, and high-performance integrated solutions. As semiconductor processes scale to smaller nodes and circuits become more complex, leveraging backside interconnect and advanced device structures like the BiSCR will remain integral strategies in the industry’s continuing quest for efficiency, reliability, and minimal form factors.

Accordingly, the teachings herein provide methods and systems of bi-directional semiconductor-controlled rectifier with direct backside contact structure. The techniques described herein may be implemented in a number of ways. Example implementations are provided below with reference to the following figures.

### Example Bi-directional Semiconductor-controlled Rectifier with Backside Contacts Structure

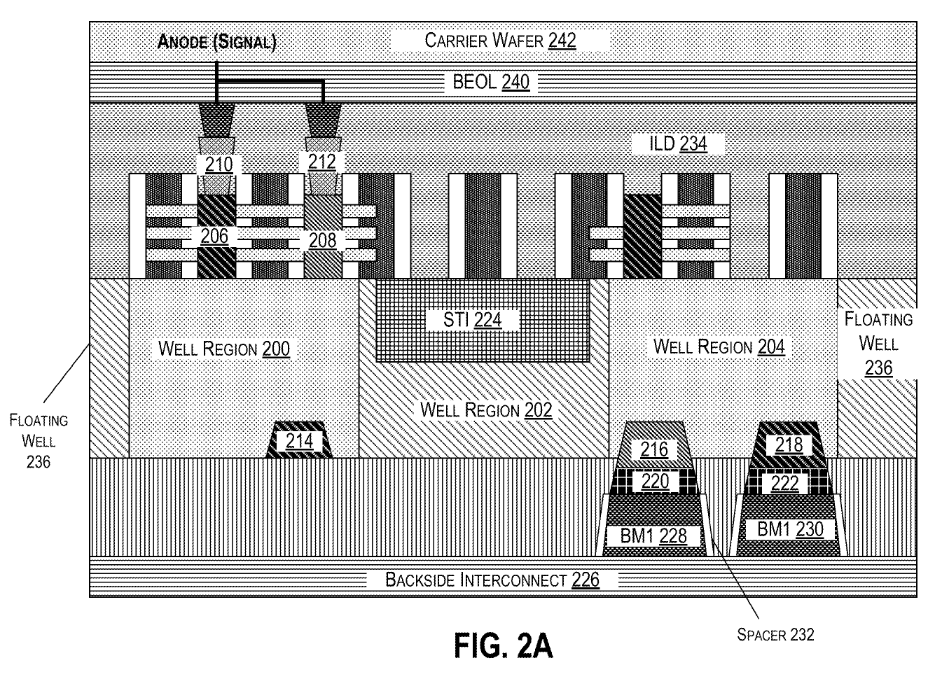

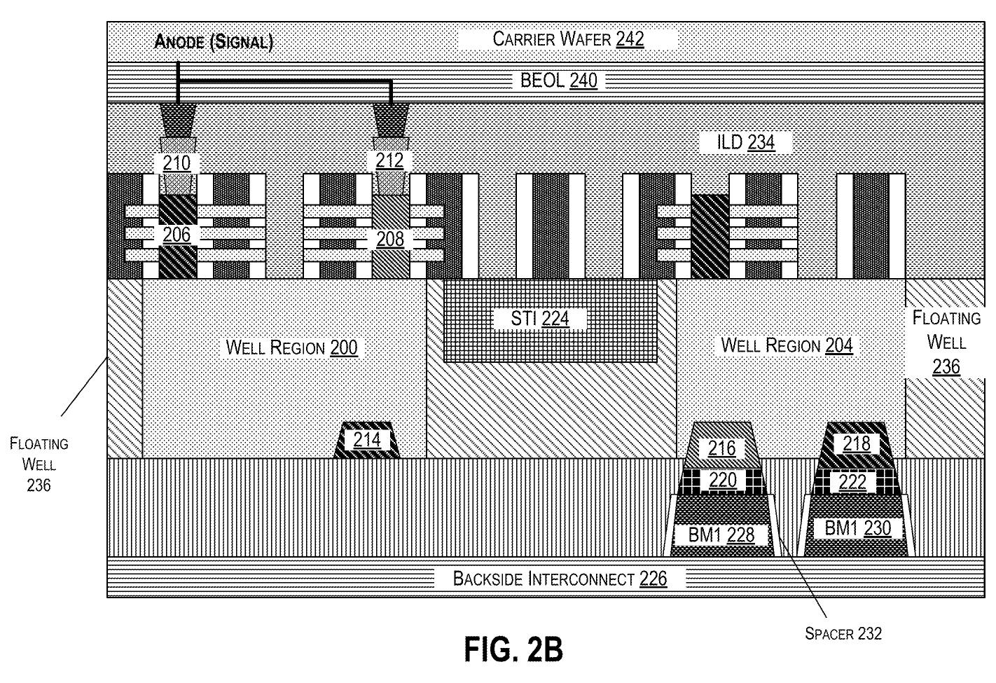

Reference now is made to FIGS. 2A-2B, which are simplified cross-sections view of a semiconductor device, consistent with an illustrative embodiment. Referring to FIG. 2A now, in various embodiments, the semiconductor device integrates both frontside and backside features, enabling enhanced current handling capabilities, robust electrostatic discharge (ESD) performance, and versatile integration within advanced integrated circuits. A first well region 200, a second well region 202, and a third well region 204 are arranged laterally adjacent to each other within a semiconductor substrate. The well regions are doped semiconductor areas defined by ion implantation or epitaxial growth techniques to produce controlled conductivity profiles. The second well region 202 is positioned between the first well region 200 and the third well region 204, ensuring that the three wells line up in a horizontal sequence. By selecting dopant types and concentrations for these wells, the device’s junctions and conduction paths are controlled. The first well region 200, second well region 202, and third well region 204 can be formed in a silicon substrate or another suitable semiconductor material, enabling compatibility with standard CMOS or BiCMOS processes. The doping concentration profiles, junction depths, and well-to-well spacing are engineered to set threshold voltages, breakdown voltages, and other critical electrical parameters of the device.

Over the first well region 200, at least one of the first frontside doped region 206 and one second frontside doped region 208 are formed. The frontside doped regions represent heavily doped areas introduced into the top surface of the wafer, after defining and patterning the wells. The first frontside doped region 206 and the second frontside doped region 208 can be formed using ion implantation followed by appropriate annealing steps to achieve the desired dopant activation and diffusion profiles. The doping type (N-type or P-type) and concentration levels are chosen to provide ohmic contacts, channel formation, or rectifying junctions as needed. In some embodiments, the frontside doped regions serve as the anode or cathode terminals of a rectifier structure, or as source/drain terminals of a transistor-like configuration, depending on the specific application and circuit design.

A first frontside contact 210 and a second frontside contact 212 are formed over the first frontside doped region 206 and the second frontside doped region 208, respectively. The frontside contacts are conductive features, and can be composed of metals such as tungsten, aluminum, copper, or metal silicides, and are introduced through standard metallization processes. By making ohmic contact to the underlying heavily doped semiconductor regions, the first frontside contact 210 and second frontside contact 212 provide a low-resistance interface for electrical signals, supply lines, or biasing nodes. Precise lithographic patterning and deposition techniques can ensure that these contacts align with the doped regions and maintain low (e.g., minimal) parasitic resistance and capacitance. Integrating the frontside contacts into the back end of line (BEOL) interconnect stack allows the semiconductor device to be readily connected to other components in the integrated circuit.

On the backside of the semiconductor device, a first backside doped region 214 is formed on a lower portion of the first well region 200. Additionally, a second backside doped region 216 and a third backside doped region 218 are formed on a lower portion of the third well region 204. The backside refers to the wafer surface opposite the frontside, and forming doped regions, there involves processes such as wafer thinning, backside implantation, epitaxial growth, or diffusion. The presence of the backside doped regions allows the device to establish vertical current paths, wherein carriers can flow from the frontside through the well regions and out the backside, or vice versa. The vertical conduction capability can be crucial in high-current applications, ESD protection structures, or vertical transistor architectures.

To electrically connect the backside doped regions to external circuitry or to internal redistribution layers, backside contacts and interconnects are incorporated. A first backside contact 220 and a second backside contact 222 can be introduced below the first backside doped region 214 and the third backside doped region 218, respectively. The first backside contact 220 and the second backside contact 222 are conductive features formed by depositing metals or metal stacks onto the backside surface after wafer thinning and backside processing steps. The backside contacts reduce the reliance on frontside routing for certain current paths, enable efficient current distribution, and can improve heat dissipation by providing shorter conduction paths to thermal sinks.

To isolate device regions and ensure stable electrical operation, shallow trench isolation, STI 224, is incorporated adjacent to the second well region 202 at the frontside of the semiconductor device. STI 224 involves etching shallow trenches into the semiconductor substrate and filling them with an insulating material, such as silicon dioxide or a low-stress liner. By electrically isolating neighboring device regions, STI 224 reduces leakage currents, prevents latch-up, and enhances overall device robustness. In a complex integrated circuit environment, STI 224 ensures that the behavior of one well region does not adversely affect its neighbors, maintaining intended device characteristics even at high currents or voltages. Below the semiconductor device lies a backside interconnect 226, providing a routing layer or network of metal lines and vias accessible from the backside. The backside interconnect 226 can be formed by depositing and patterning one or more metal layers on the wafer’s backside. The metal layers can be connected to the first backside contact 220 and the second backside contact 222 through a first backside metal contact 228 and a second backside metal contact 230, respectively. The term backside metal contact can refer to vertically oriented conductive elements that extend from the backside doped regions and contacts down to the backside interconnect 226. The vertical interconnect structures can employ tungsten plugs, copper-filled vias, or other advanced metallization schemes that are compatible with wafer thinning and backside processing technologies.

Over the sidewalls of the first backside metal contact 228 and the second backside metal contact 230, a spacer 232 is formed. The spacer 232 can be an insulating layer conformally deposited and then anisotropically etched to remain only on the sidewalls of the contacts. By including spacer 232, the device ensures that the backside metal contacts are electrically isolated from each other and from surrounding regions. Spacers 232 also help control the effective contact area, reduce parasitic capacitances, and maintain the integrity of dielectric layers, which can be crucial in achieving stable and predictable electrical performance under high-current conditions.

The semiconductor device can incorporate a vertical bi-directional semiconductor-controlled rectifier (SCR) architecture. A bi-directional SCR is a four-layer structure that can conduct current once triggered, regardless of the polarity of the applied voltage. Vertical conduction paths, formed by the combination of frontside and backside doped regions and contacts, enable current flow from top to bottom or bottom to top through the stack of semiconductor layers. By placing an anode region on the frontside and a cathode region on the backside, or vice versa, the semiconductor device can clamp voltage transients and shunt large currents during ESD events or other fault conditions. The incorporation of a p-well region contacting the anode or cathode junction can be wired to the BEOL 240 on the frontside, allowing this SCR structure to integrate seamlessly into standard CMOS interconnect frameworks.

On the backside, a cathode junction and a corresponding p-well contact can be formed, ensuring that the SCR action is not limited to a single direction. The symmetrical configuration effectively doubles the protection capability against voltage surges of either polarity. The second backside doped region 216 and the third backside doped region 218 can be chosen to be N-type and P-type doped regions, respectively, or vice versa depending on the desired conduction mode and triggering behavior. By selecting dopant types, the semiconductor device can tailor the polarity of the junctions formed and optimize the turn-on characteristics of the SCR. Furthermore, allowing the backside doped regions to partially intrude into the third well region 204 ensures stable junction formation, robust mechanical anchoring, and a well-defined depletion region for predictable breakdown and snapback behavior.

The device can be vertically isolated by a low-k interlayer dielectric, ILD 234. A low-k dielectric material is chosen because it has a dielectric constant lower than that of conventional silicon dioxide, thereby reducing parasitic capacitances between interconnect layers. The reduction in parasitic effects enhances the device’s switching speed, reduces dynamic power dissipation, and improves high-frequency performance. Vertical isolation using ILD 234 also ensures that stacked metal layers, contacts, and doped regions maintain very low (e.g., minimal) interference with each other, enhancing the overall electrical integrity of the device. Meanwhile, horizontal isolation can be provided by floating N-wells 236, which reduces unwanted charge coupling, leakage currents, and crosstalk between adjacent device elements. Floating N-wells 236 are well regions that are not tied to a fixed potential, acting as barriers or guard rings that help control device-to-device interactions without imposing additional routing overhead. The vertical current conduction path enabled by backside doped regions and backside contacts ensures that large transient currents can be handled efficiently, reducing the likelihood of localized heating and catastrophic breakdown. The integration of an SCR-like structure in a vertical orientation, combined with engineered doping profiles, ensures that the device triggers at controlled voltages and maintains stable conduction once turned on, providing an effective clamp against harmful voltage spikes.

Since the semiconductor device leverages backside processing, it can simplify frontside routing and free up valuable real estate on the top metal layers for additional logic, memory cells, or analog circuitry. Such an approach is particularly advantageous in high-density integrated circuits where space is at a premium. The backside interconnect 226 and backside contacts offer vertical integration opportunities, further enabling advanced 3D-IC stacking or chiplet-based architectures. Additionally, by carefully controlling doping and introducing ballasting resistance through particular doping profiles, the device can ensure uniform current distribution during ESD events, preventing current crowding in a single region and thus improving overall reliability.

Implementing STI 224 prevents unintended current paths and ensures each well region and doped area operates as intended. The presence of a spacer 232 on the backside metal contacts enhances manufacturing tolerances, provides well-defined interface boundaries, and ensures that the conduction paths maintain stable and predictable I-V characteristics. The ability to form N-type and P-type regions on both the frontside and backside, and to arrange them in three well regions lined adjacent, gives designers flexibility in defining complex transistor, diode, or thyristor configurations. The second well region 202 sandwiched between the first well region 200 and the third well region 204 acts as a central layer that can serve as a base or an intermediate junction for the SCR. The layering and arrangement also facilitate bi-directional conduction, as each half of the device can trigger and conduct independently under opposite voltage polarities.

By employing floating N-wells 236 horizontally and ILD 234 vertically, the semiconductor device achieves a three-dimensional isolation scheme that preserves signal integrity, reduces interference, and promotes stable operation under various load conditions. The combination of vertical and horizontal isolation techniques is increasingly important as integrated circuits scale to smaller nodes, higher speeds, and greater complexity. The isolation ensures that even under extreme ESD conditions, or when dealing with large transient currents, the device maintains well-defined conduction paths and stable trigger points. A carrier wafer 242 can bond the semiconductor device to other devices.

Referring now to FIG. 2B, in some embodiments, the semiconductor device is a vertical bi-directional semiconductor-controlled rectifier (SCR) structure arranged to conduct current along a vertical axis of the semiconductor substrate. The semiconductor device as shown in FIG. 2B includes two frontside doped regions that are not connected. The device includes an anode and a corresponding n+ diffusion in the same p-well wired to a back end of line (BEOL) on the frontside, and a cathode junction and a corresponding p-well contact formed on the backside, thus enabling current conduction and control in both forward and reverse directions. A first well region 200, a second well region 202, and a third well region 204 are formed adjacent to each other within a semiconductor substrate. The well regions are created using doping processes such as ion implantation and thermal diffusion to establish areas of controlled conductivity and polarity. The well regions define the fundamental electrical environment in which the device’s junctions and conduction paths are formed. The second well region 202 is located between the first well region 200 and the third well region 204, providing a sequence of wells arranged in a horizontal plane. This arrangement allows the device designer to precisely configure transistor-like junctions and thyristor-like conduction mechanisms along both vertical and horizontal dimensions. At the frontside of the semiconductor device, over the first well region 200, a first frontside doped region 206 and a second frontside doped region 208 are formed. The doped regions are heavily doped semiconductor areas designed to create low-resistance junctions or ohmic contacts. The doping types and concentration levels of these frontside regions can be tailored to achieve desired electrical properties, such as low forward voltage drop or controlled trigger voltages. The choice of doping species (e.g., boron for P-type or phosphorus/arsenic for N-type) and dopant profiles ensures stable device performance under a wide range of operating conditions.

On top of the first frontside doped region 206 and the second frontside doped region 208, a first frontside contact 210 and a second frontside contact 212 are formed. The contacts provide a conductive interface between the underlying semiconductor regions and the BEOL metallization stack on the frontside of the wafer. The contacts are typically composed of metals or metal silicides deposited through thin-film techniques and patterned using advanced lithography. Their alignment and dimensions are carefully controlled to reduce (e.g., minimize) contact resistance and ensure robust current flow between the device active regions and the metal interconnect layers above. The anode portion of the vertical bi-directional SCR is defined at least in part by the first well region 200 and the first frontside doped region 206 and the second frontside doped region 208, along with their corresponding contacts. By connecting the anode and a corresponding n+ diffusion in the same p-well on the frontside to the BEOL interconnects, the device enables efficient routing of signals and currents into the top metal layers of the integrated circuit. The frontside anode configuration can share a p-well contact that stabilizes the local potential of a P-type region within or adjacent to the first well region 200, ensuring consistent transistor action and stable SCR triggering behavior.

On the backside of the semiconductor device, a first backside doped region 214 and a second backside doped region 216 are formed on a lower portion of the third well region 204. The backside doped regions are introduced after wafer thinning, backside grinding, or other backside processing steps that expose the lower surfaces of the wells. By implanting or diffusing dopants from the backside and carefully annealing, the regions can be tailored to provide well-defined junctions that couple into the semiconductor structure from below. Below the first backside doped region 214 and the second backside doped region 216, a first backside contact 220 and a second backside contact 222 are formed.

In this configuration, the cathode portion of the vertical bi-directional SCR is defined at least in part by the third well region 204 and the backside doped regions along with their corresponding backside contacts. The cathode junction formed on the backside of the semiconductor device can be of opposite polarity to the anode junction on the frontside. The presence of a corresponding p-well contact on the backside ensures that a suitable reference potential or doping environment is maintained, stabilizing the SCR conduction path when triggered. The vertical bi-directional SCR formed by this arrangement can conduct current in both forward and reverse directions, depending on the polarity of the applied voltage and the conditions that lead to triggering its internal regenerative conduction mechanism. When the voltage across the device in one direction exceeds a certain threshold (the trigger voltage), a small initial current triggers the device’s internal transistor pairs, causing it to switch into a low-resistance conduction state and carry large amounts of current. Due to the symmetrical arrangement and doping profiles, reversing the polarity of the applied voltage can trigger the device in the opposite direction, enabling bi-directional operation.

Integrating an anode and its n+ diffusion in the same p-well at the frontside, along with a cathode junction and its p-well contact at the backside, creates a structure that is particularly well-suited for electrostatic discharge (ESD) protection applications. Under ESD conditions, the vertical bi-directional SCR can clamp voltage spikes from either polarity, preventing harmful transients from reaching sensitive internal nodes of the integrated circuit. By channeling large surge currents through the vertical conduction path, the device dissipates the ESD energy in a controlled manner, reducing localized heating and reducing (e.g., minimizing) damage to the substrate or metallization layers. The second well region 202 situated between the first and the third well regions ensures that appropriate junction sequences form when the doping profiles are laid out. For instance, an N-well region surrounded by P-well regions or vice versa can establish PNPN or NPNP sequences that define SCR action.

The presence of first and second backside doped regions, as well as first and second backside contacts, provides design freedom to partition functions between frontside and backside. For example, placing the cathode on the backside can reduce frontside crowding and free up valuable real estate on the top metal layers for other circuit components. Additionally, backside processing techniques allow for integration with advanced wafer-level packaging, through-silicon vias, or other 3D integration methods that enhance performance, reduce form factor, and improve reliability. Ballasting resistance and controlled doping gradients can be incorporated into the arrangement of wells, doped regions, and contacts to ensure uniform current distribution during transient events. This uniformity prevents the current from crowding into a single conduction path, which can lead to localized heating and early device failure. Instead, the vertical bi-directional SCR structure promotes even conduction through multiple parallel current paths, increasing the total ESD current-handling capability.

In an integrated circuit environment, the frontside anode and n+ diffusion in the same p-well wired to the BEOL layers can be connected to supply lines, reference voltages, or sensitive circuit nodes that require robust protection. The backside cathode junction and corresponding p-well contact can be tied to ground references, power return paths, or other circuit elements that benefit from vertical conduction and efficient current sinking. The result is a versatile component that can protect against ESD pulses of both polarities, respond quickly to voltage spikes, and revert to a non-conductive state after the transient passes. The vertical bi-directional SCR structure can be scaled to match various circuit requirements. By adjusting well doping levels, junction depths, contact sizes, and the spatial arrangement of doped regions, the parameters such as trigger voltage, holding voltage, and better (e.g., maximum) current capacity can be tuned. Such a scalability allows the device to serve a wide range of applications, from low-voltage IO pads in consumer electronics to high-voltage industrial or automotive systems where large ESD events are common.

Additionally, integrating the p-well contacts into both frontside and backside structures ensures stable and well-defined transistor action within the SCR. The p-well contacts maintain proper potential references for the internal PN junctions that comprise the SCR stack, preventing undesired shifts in threshold levels or minority carrier injection. The stability translates into predictable switching behavior and more consistent ESD performance over the device’s lifetime.

### Example Fabrication of A Bi-directional Semiconductor-controlled Rectifier with Backside Contacts Structure

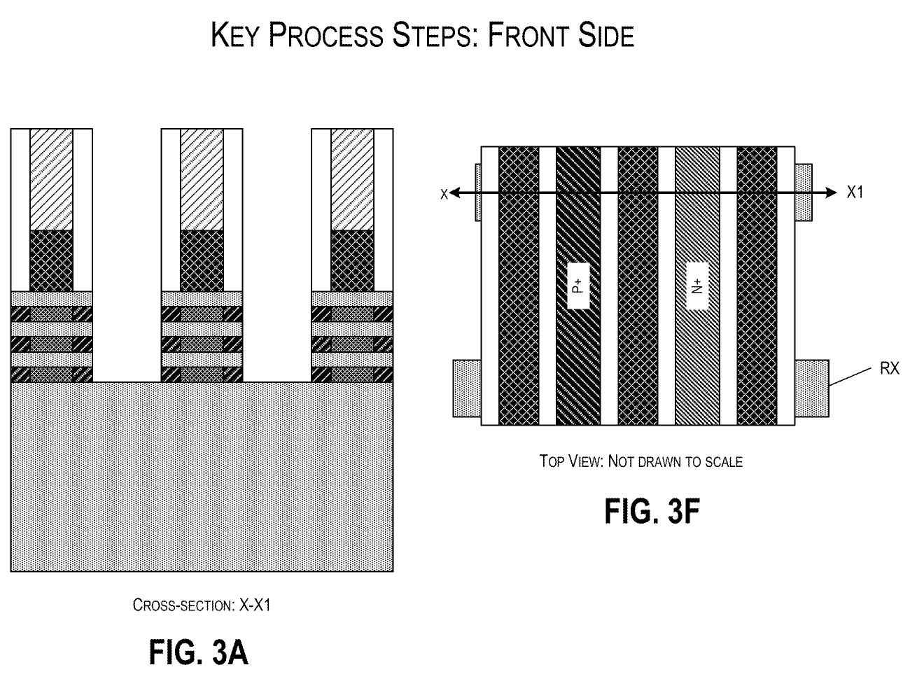

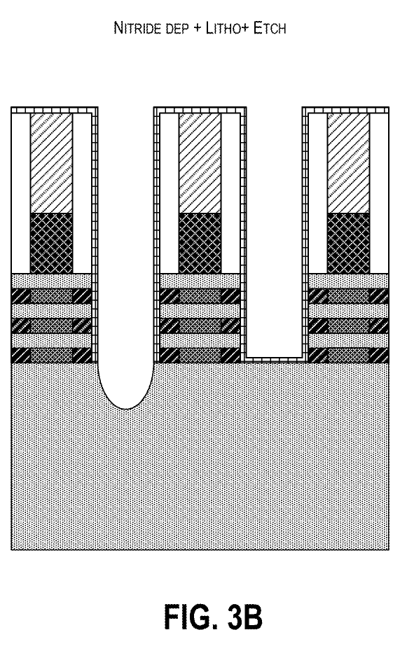

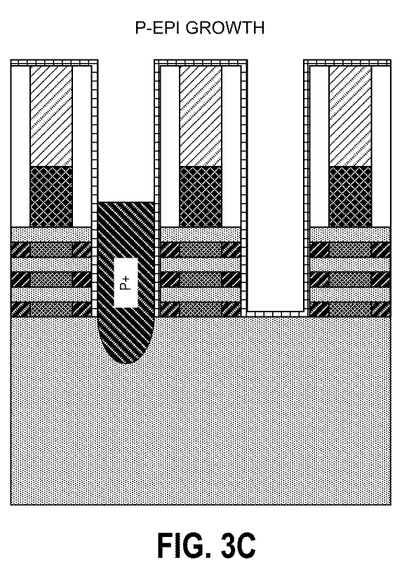

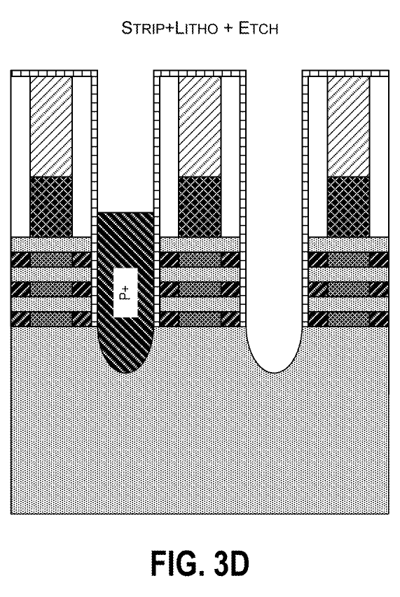

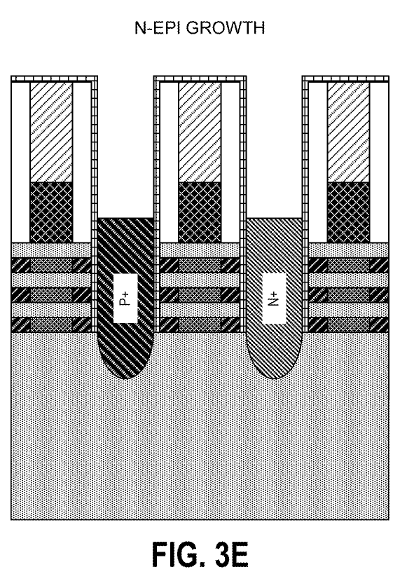

With the foregoing description of an example semiconductor device, it may be helpful to discuss an example process of manufacturing the same. To that end, FIGS. 3-19 illustrate various acts in the manufacture of a semiconductor device, consistent with illustrative embodiments. Figures denoted by A show the acts of fabrication of the active device in an SCR-dense region, and figures denoted by B show the acts of fabrication of the transistor region.

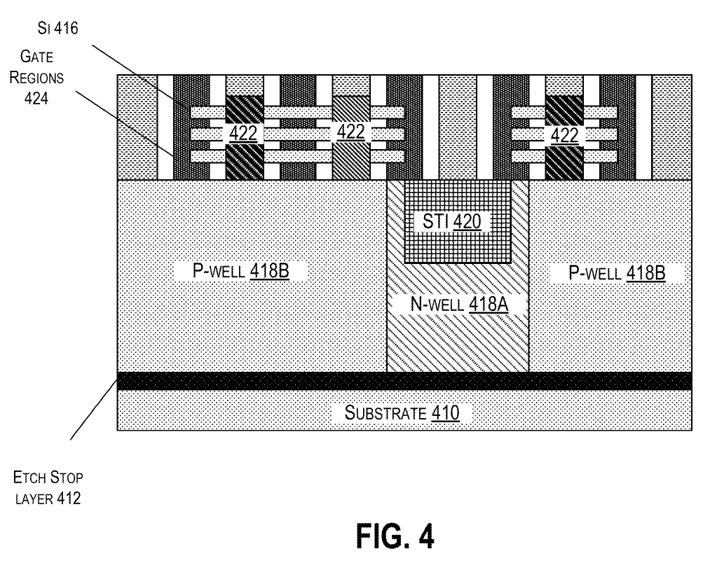

FIGS. 3A-3F illustrate the key acts in preparing the frontside of the semiconductor device. FIGS. 4-19 illustrate such acts in more details. Reference now is made to FIG. 4, which is a simplified cross-section view of a semiconductor device, after the front end of line processes, consistent with an illustrative embodiment. The semiconductor device can include a substrate 410, an etch stop layer 412, a plurality of alternating layers of Si 416, an N-well 418A, a P-well 418B, STI 420, doped regions 422, and gate regions 424.

In the illustrative example depicted in FIG. 4, the semiconductor device is depicted as being on silicon as the substrate 410, while it will be understood that other types as the substrate 410 can be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrate 410 can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, the etch stop layer 412 is formed between the substrate 410. The etch stop layer 412 can be a thin layer of material incorporated into the structure of the semiconductor device to provide a selective barrier against etching processes, preventing further removal of underlying materials during fabrication.The etch stop layer 412 can enable precise control over the etching depth and help define the desired device dimensions. The etch stop layer 412 can further provide a stopping point for the etching process, ensuring that specific layers or regions are not etched beyond a certain point, leading to accurate patterning and control of critical features.The etch stop layer 412 can create a distinct separation between different layers or components within the device structure, and prevent the undesired etching of underlying layers or materials, enabling the creation of complex, multi-layered structures with well-defined interfaces and boundaries.In some embodiments, the etch stop layer 412 acts as a protective barrier for sensitive or delicate materials to shield such materials from aggressive etchants, preventing damage or degradation during subsequent fabrication steps.

In some embodiments, prior to forming the etch stop layer 412, the substrate 410 is prepared by cleaning and removing any impurities or oxide layers. The etch stop layer 412 is deposited onto the substrate 410 using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 412 can then be selectively etched, stopping at a predetermined depth, while protecting the underlying layers. After the etching process, the remaining photoresist can be removed through stripping techniques. While in some embodiments, SiGe is used to form the etch stop layer 412, in some embodiments, silicon nitride (SiN), silicon oxide (SiO2), or silicon oxynitride (SiON) can be used as the etch stop layer 412.

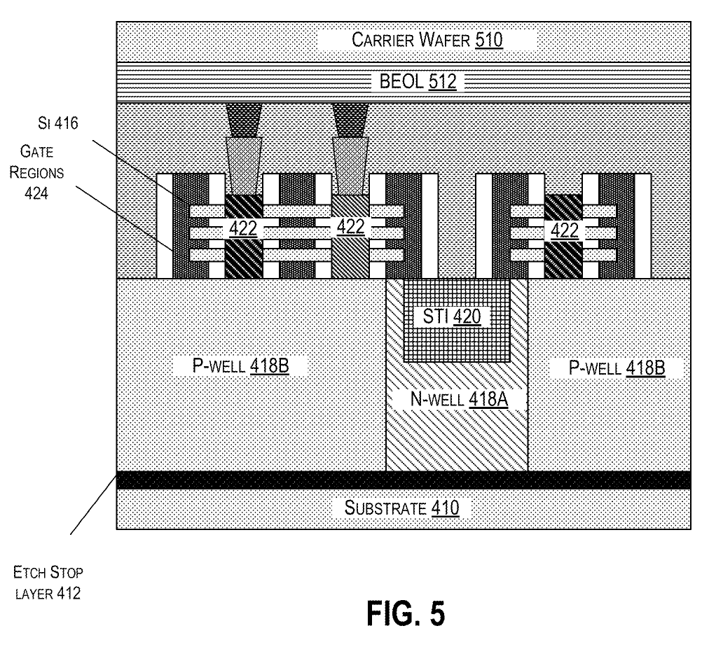

FIG. 5 illustrates a semiconductor device after the middle of line and back end of line processes, in accordance with some embodiments. In some embodiments, the back end of line, BEOL 510, is formed over the semiconductor device followed by formation of the carrier wafer 512. The BEOL 510 can include metal interconnects, e.g., wires and metal lines, and insulating layers that connect the various components of the semiconductor device and enable them to function as a cohesive unit.

In various embodiments, carrier wafer bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices. The metal layer can be deposited or transferred onto one or both semiconductor device surfaces, and the semiconductor devices can then be brought into contact and subjected to temperature and pressure to create a metallic bond.

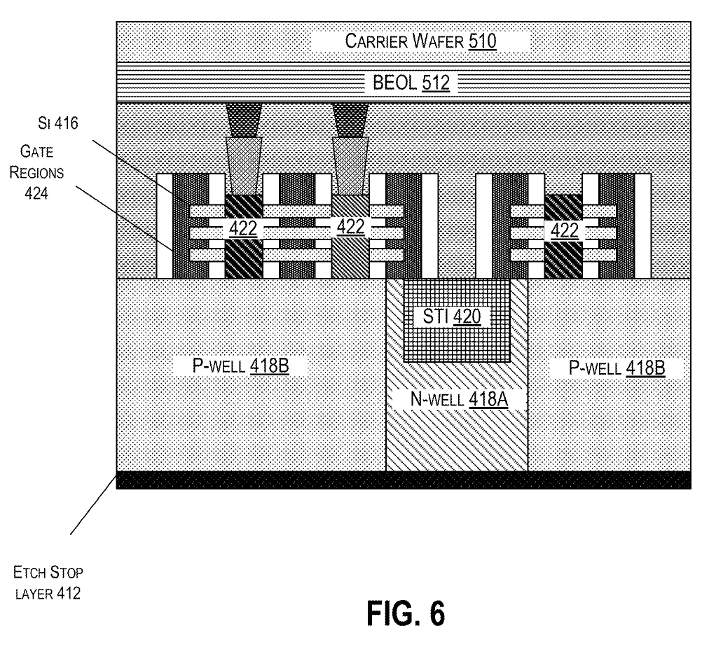

FIG. 6 illustrates a semiconductor device after the removal of the substrate, in accordance with some embodiments. In some embodiments, substrate is removed and the etch stop layer 412 is exposed.

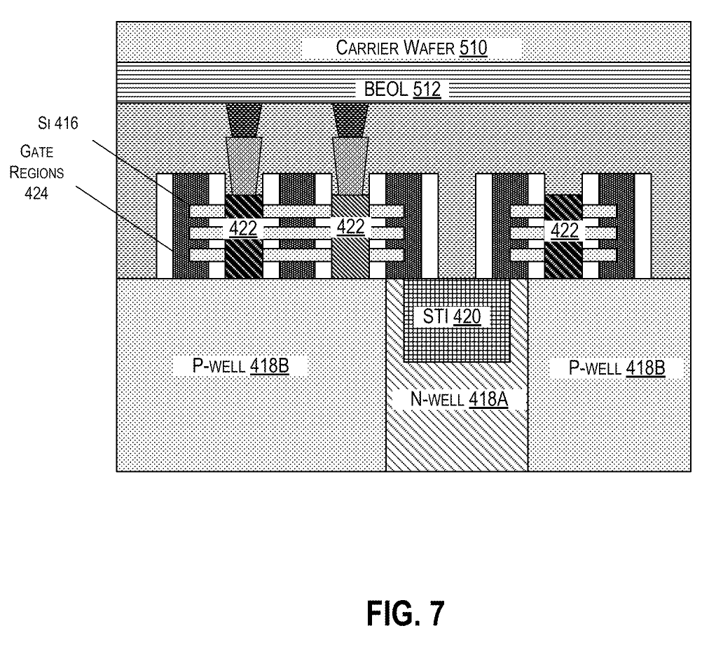

FIG. 7 illustrates a semiconductor device after the removal of the etch stop layer, in accordance with some embodiments. In some embodiments, the etch stop layer is removed.

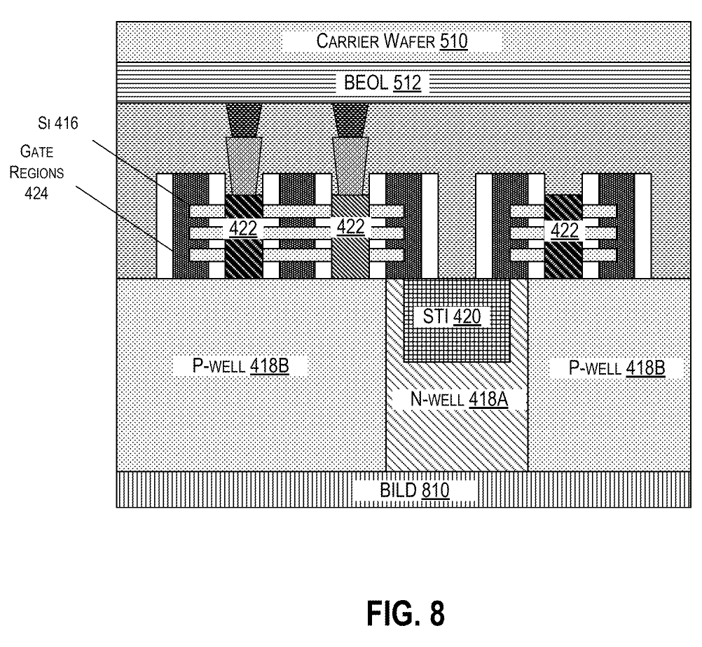

FIG. 8 illustrates a semiconductor device after the formation of backside interlayer dielectric, in accordance with some embodiments. In some embodiments, the BILD 810 is formed on the backside of the semiconductor device.

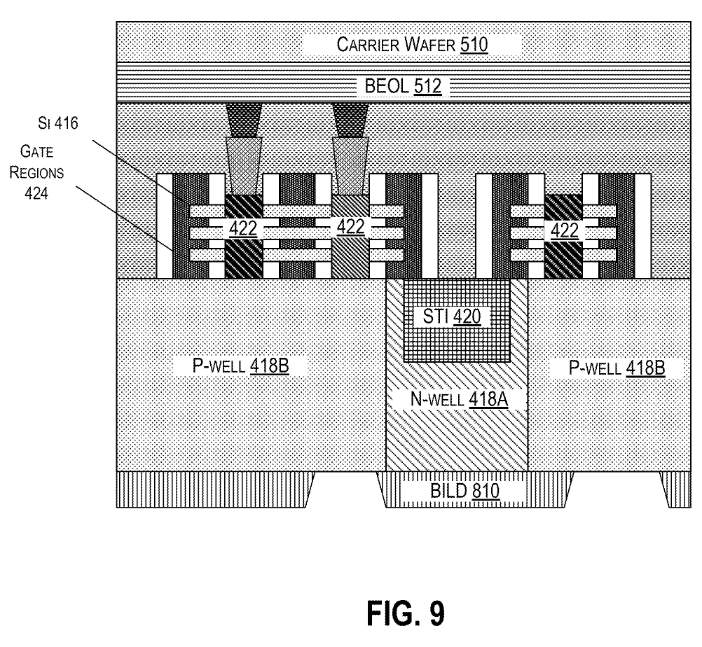

FIG. 9 illustrates a semiconductor device after the patterning of the backside of the semiconductor device, in accordance with some embodiments. In some embodiments, portions of the BILD and the P-well are removed.

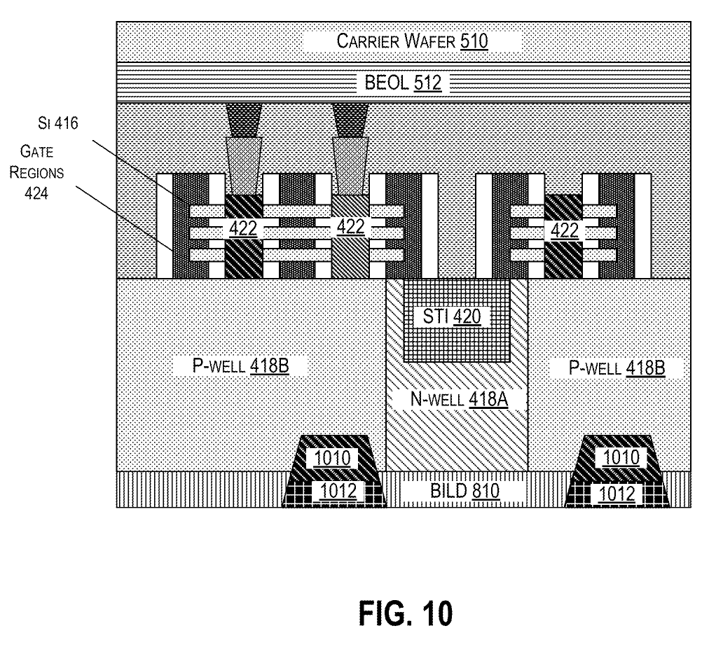

FIG. 10 illustrates a semiconductor device after the formation of doped regions, in accordance with some embodiments. In some embodiments, the backside doped regions 1010 are formed intruding the N-well 418A and P-well 418B. Backside contacts, BSCA 1012, are formed below the backside doped regions 1010 within the BILD 810. The backside doped regions 1010 can be doped with a similar dopant.

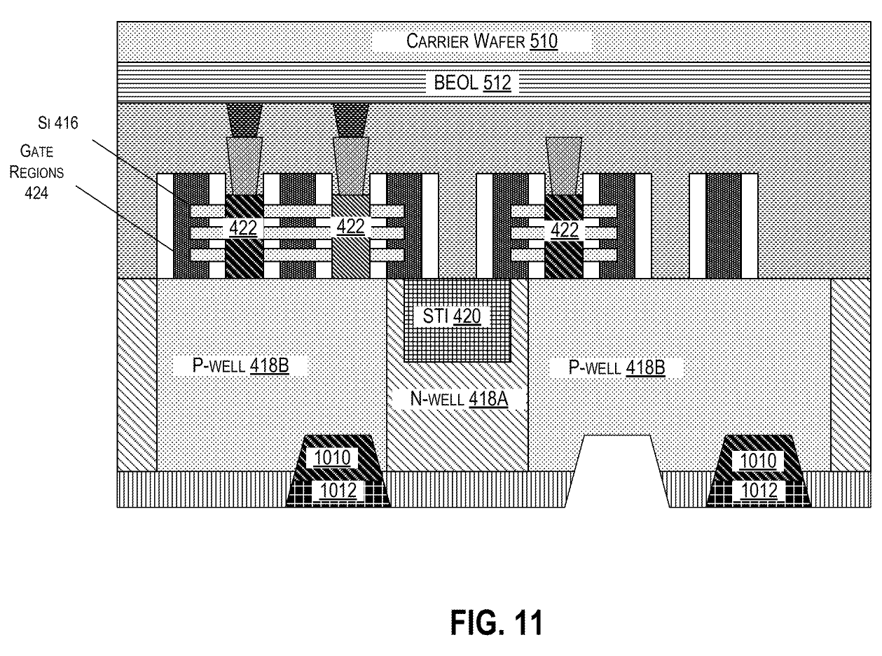

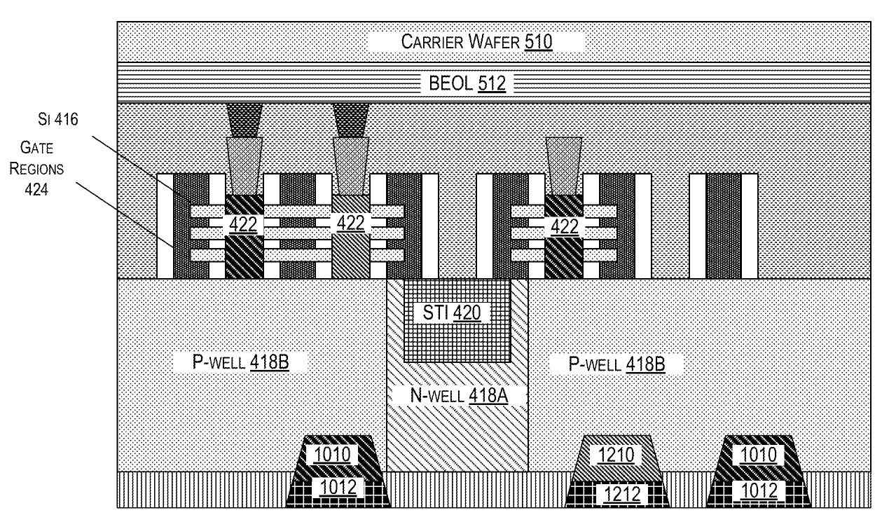

FIG. 11 illustrates a semiconductor device after the patterning of the backside doped region, in accordance with some embodiments. In some embodiments, portions of the BILD and the P-well are removed for patterning an additional backside doped region.

FIG. 12 illustrates a semiconductor device after the formation of a doped region, in accordance with some embodiments. In some embodiments, the backside doped region 1210 is formed intruding the P-well 418B. Backside contact, BSCA 1212, is formed below the backside doped region 1210 within the BILD 810.

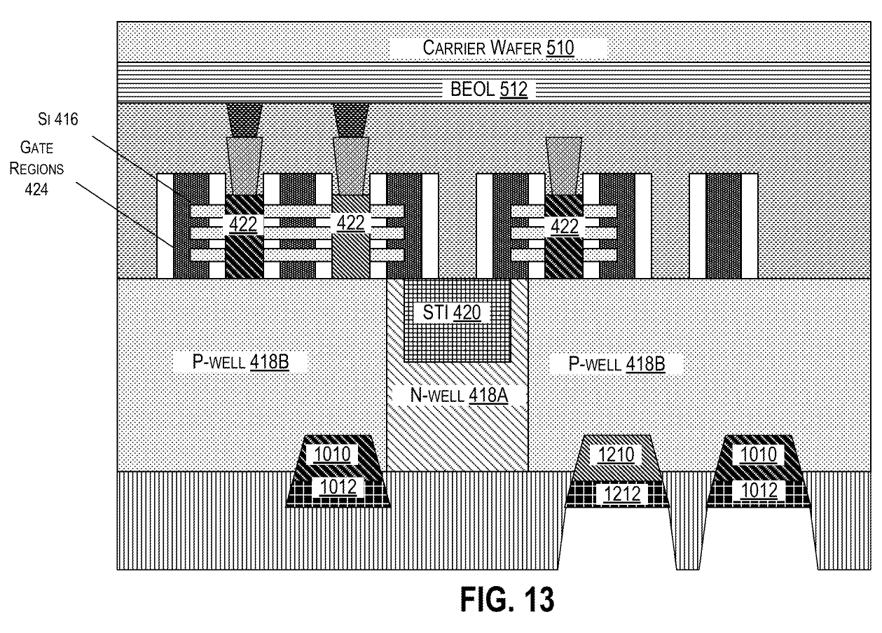

FIG. 13 illustrates a semiconductor device after the patterning of the backside contact, in accordance with some embodiments. In some embodiments, additional BILD is formed over the backside of the semiconductor device. Portions of the BILD are removed to expose two adjacent BSCA.

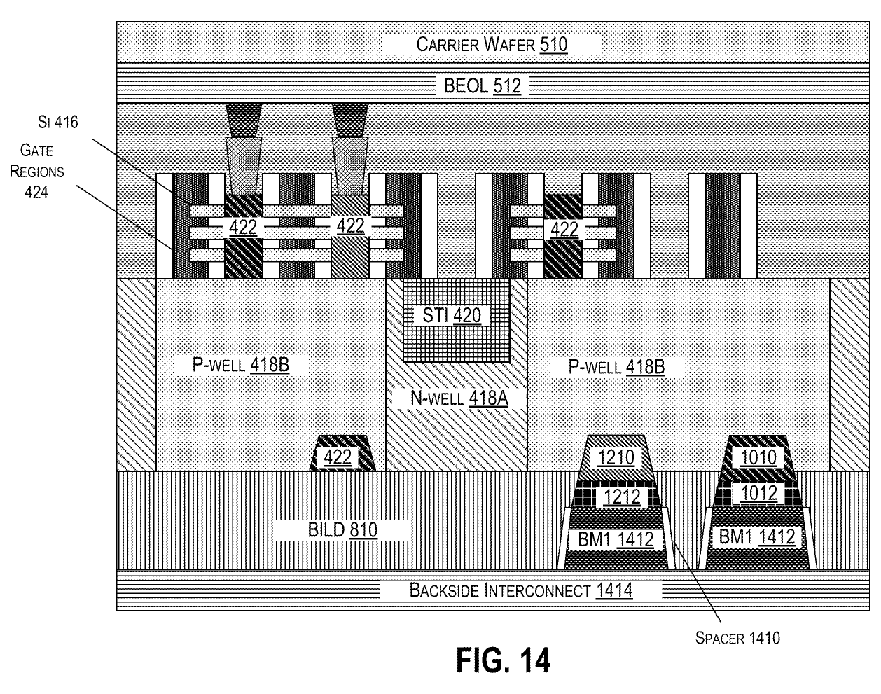

FIG. 14 illustrates a semiconductor device after the formation of spacer, in accordance with some embodiments. In some embodiments, a spacer 1410 is formed over sidewalls of the removed portions of the BILD. Backside metal contacts, BM1 1412, are formed by filling the remaining removed portions of the BILD. A backside interconnect 1414 is formed on the backside of the semiconductor device.

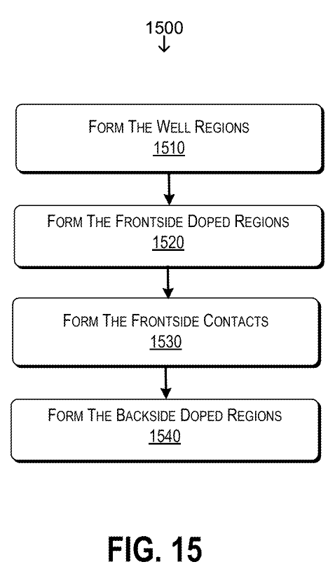

FIG. 15 illustrates a block diagram of a method 1500 for forming the semiconductor device, in accordance with some embodiments. As shown by block 1510, a first well region, a second well region and a third well region adjacent to each other are formed.

As shown by block 1520, a first frontside doped region and a second frontside doped region are formed.

As shown by block 1530, a first frontside contact and a second frontside contact are formed.

As shown by block 1540, a first backside doped region and a second backside doped region are formed.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a first well region, a second well region, and a third well region adjacent to each other, wherein the second well region is located between the first well region and the third well region;
a first frontside doped region and a second frontside doped region over the first well region;
a first frontside contact and a second frontside contact over the first frontside doped region and the second frontside doped region, respectively;
a first backside doped region on a lower portion of the first well region on a backside of the semiconductor device; and
a second backside doped region and a third backside doped region on a lower portion of the third well region on the backside of the semiconductor device, respectively.

2. The semiconductor device of claim 1, further comprising:
a first backside contact and a second backside contact below the second backside doped region and the third backside doped region, respectively; and
shallow trench isolation (STI) between the second well region and a frontside of the semiconductor device.

3. The semiconductor device of claim 2, further comprising:
a backside interconnect below the semiconductor device;
a first backside metal contact and a second backside metal contact connecting the first backside contact and the second backside contact to the backside interconnect, respectively; and
a spacer over sidewalls of the first backside metal contact and the second backside metal contact.

4. The semiconductor device of claim 1, wherein the semiconductor device is a vertical bi-directional semiconductor-controlled rectifier (SCR), and wherein a signal is connected to a P+ and an N+ diffusion in the first well region are wired to a back end of line (BEOL) on a frontside of the semiconductor device.

5. The semiconductor device of claim 4, wherein a cathode junction and a corresponding p-well contact are formed on the backside of the semiconductor device.

6. The semiconductor device of claim 1, wherein the second backside doped region is an N-type doped region, and wherein the third backside doped region is a P-type doped region.

7. The semiconductor device of claim 1, wherein the second backside doped region and the third backside doped region are at least partially intruding into the third well region.

8. The semiconductor device of claim 1, wherein the semiconductor device is vertically isolated by a low-k interlayer dielectric and horizontally by floating N-wells.

9. The semiconductor device of claim 1, wherein the semiconductor device is a bi-directional semiconductor-controlled rectifier.

10. A method for fabrication of a semiconductor device, the method comprising:
forming a first well region, a second well region and a third well region adjacent to each other, wherein the second well region is located between the first well region and the third well region;
forming a first frontside doped region and a second frontside doped region over the first well region;
forming a first frontside contact and a second frontside contact over the first frontside doped region and the second frontside doped region, respectively;
forming a first backside doped region on a lower portion of the first well region on a backside of the semiconductor device; and
forming a second backside doped region and a third backside doped region on a lower portion of the third well region on the backside of the semiconductor device, respectively.

11. The method of claim 10, further comprising:
forming a first backside contact and a second backside contact below the first backside doped region and the third backside doped region, respectively; and
forming shallow trench isolation (STI) between the second well region and a frontside of the semiconductor device.

12. The method of claim 11, further comprising:
forming a backside interconnect below the semiconductor device;
forming a first backside metal contact and a second backside metal contact connecting the second backside contact and a third backside contact to the backside interconnect, respectively; and
forming a spacer over sidewalls of the first backside metal contact and the second backside metal contact.

13. The method of claim 10, further comprising:
electrically connecting an anode and a corresponding n+ diffusion in a same p-well to a back end of line (BEOL) on a frontside of the semiconductor device, wherein the semiconductor device is a vertical bi-directional semiconductor-controlled rectifier (SCR).

14. The method of claim 13, further comprising:
forming a cathode junction and a corresponding p-well contact on the backside of the semiconductor device.

15. The method of claim 10, further comprising:
doping the second backside doped region with an N-type dopant; and
doping the third backside doped region with a P-type dopant.

16. The method of claim 10, further comprising at least partially intruding the second backside doped region and the third backside doped region into the third well region.

17. The method of claim 10, further comprising:
vertically isolating the semiconductor device by a low-k interlayer dielectric; and horizontally isolating the semiconductor device by floating N-wells.

18. The method of claim 10, wherein the semiconductor device is a bi-directional semiconductor-controlled rectifier.

19. A semiconductor device, comprising a vertical bi-directional semiconductor-controlled rectifier (SCR), wherein:
an anode and a corresponding n+diffusion in a same p-well are wired to a back end of line (BEOL) on a frontside of the semiconductor device; and
a cathode junction and a corresponding p-well contact are formed on a backside of the semiconductor device.

20. The semiconductor device of claim 19, further comprising:
a first well region, a second well region and a third well region adjacent to each other, wherein the second well region is located between the first well region and the third well region;
wherein the anode comprises:
a first frontside doped region and a second frontside doped region over the first well region; and
a first frontside contact and a second frontside contact over the first frontside doped region and the second frontside doped region, respectively, and
wherein the cathode junction comprises:
a first backside doped region and a second backside doped region on a lower portion of the third well region on the backside of the semiconductor device, respectively; and
a first backside contact and a second backside contact below the first backside doped region and the second backside doped region, respectively.
